(19) United States
(12) Patent Application Publication
(10) Pub. No.: US 2017/0044310 A1
(43) Pub. Date: Feb. 16, 2017

(54) ORGANIC HETEROPOLYMER AND METHOD FOR MANUFACTURING SAME

(71) Applicants: DAICEL CORPORATION, Osaka-shi, Osaka (JP); Tokyo Institute of Technology, Tokyo (JP)

(72) Inventors: Ikuyoshi TOMITA, Tokyo (JP); Yoshimasa MATSUMURA, Tokyo (JP); Ichiro TAKASE, Himeji-shi (JP); Kazuhisa FUKUI, Himeji-shi (JP)

(73) Assignees: Daicel Corporation, Osaka-shi, Osaka (JP); Tokyo Institute of Technology, Tokyo (JP)

(21) Appl. No.: 15/303,676

(22) PCT Filed: Apr. 24, 2015
(86) PCT No.: PCT/JP2015/062587

§ 371 Date: Oct. 12, 2016

(30) Foreign Application Priority Data
May 8, 2014 (JP) 2014-097147
Oct. 16, 2014 (JP) 2014-211941

(51) Int. Cl. C08G 61/12; H01L 51/00; H01G 9/20; C09B 69/10

(52) U.S. Cl. CPC C08G 61/128; C09B 69/109; H01L 51/0043; H01L 51/0036; H01G 9/2059; C08G 2261/12; C08G 2261/3223; C08G 2261/3227; C08G 2261/312; C08G 2261/91; H01L 51/0558

(57) ABSTRACT

The organic heteropolymer of this invention is useful for forming an organic semiconductor and is a copolymeric heteropolymer having a constitutional unit represented by the formula (1) and a constitutional unit represented by the formula (2):

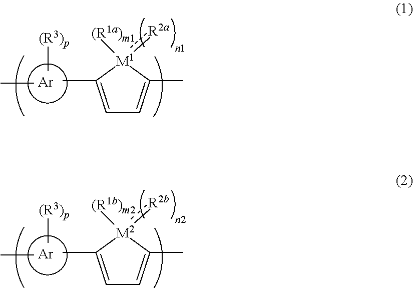

wherein M¹ and M² each represent a heteroatom selected from a group 8 element, a group 9 element, a group 10 element, a group 14 element, a group 15 element, and a group 16 element of the Periodic Table, and are different in group; M¹ and M² each have a valence v of 2 to 6; R^{1a} and R^{1b} each represent a halogen atom, an alkyl group, a cycloalkyl group, an aryl group, or a heteroaryl group; R^{2a} and R^{2b} each represent a halogen atom, an alkyl group, a cycloalkyl group, an aryl group, a heteroaryl group, a univalent or bivalent heteroatom selected from a group 16 element and a group 11 element of the Periodic Table, or a metal atom forming a complex with a ligand; m1, m2, n1, and n2 each denote 0 or 1; a ring Ar represents an aromatic ring; R³ represents a straight- or branched-chain alkyl group, a straight- or branched-chain alkoxy group, or a straight- or branched-chain alkylthio group; and p denotes 0 or an integer of 1 to 3.

### TECHNICAL FIELD

The present invention relates to organic heteropolymers containing different heterocycles useful as organic semiconductors or sensitizers (sensitizing dyes) of electronic devices (e.g., semiconductor elements and photoelectric conversion elements), and also relates to processes for producing the organic heteropolymers.

### BACKGROUND ART

Many organometallic compounds as typified by metal phthalocyanines have a unique electronic state or a very stable molecular structure due to a bond between an organic molecule thereof and a metal thereof. From these characteristics, the organometallic compounds have been used as organic pigments or others from long ago.

The organometallic compounds, which have a response to an external energy such as heat, light, or an electric field, are nowadays in widespread use in electronics fields including sensitive materials for electrophotographic printers and recording media such as compact disk-recordable (CD-R). In particular, these days an organometallic compound is noticed for a function thereof as an organic semiconductor and is studied on utilization for an organic transistor or an organic thin-film solar cell. An electronic device including an organic semiconductor is producible by printing, and thus there is the hope that the electronic device is mass-producible at a lower price compared with an inorganic device.

Many conventional organometallic compounds are insoluble or hardly soluble in a solvent and are formed into films mainly by vacuum deposition. Accordingly, electronic devices produced are unfortunately expensive.

In order to solve such a problem, Japanese Patent Application Laid-Open Publication No. 2011-162575 (JP-2011-162575A, Patent Document 1) discloses that, for example, a metal trisalkyl-4-substituted amide-phthalocyanine is produced by allowing a 4-substituted amide phthalonitrile (such as 4-acetamide phthalonitrile or 4-pyridylamide phthalonitrile) to react with a 4-alkyl phthalonitrile (such as 4-t-butyl phthalonitrile) in the presence of a metal salt (a salt of a metal such as Ni, Zn, or Cu). This document also discloses that a soluble substituted phthalocyanine having an amino group is produced by hydrolyzing the phthalocyanine compound. The phthalocyanine derivative has a large sterically hindered functional group, such as t-butyl group, on phthalocyanine. This prevents stacking between phthalocyanines, and the phthalocyanine derivative is soluble in a solvent.

Unfortunately, introduction of the functional group that hinders stacking makes intermolecular electron transfer difficult, and such a phthalocyanine derivative has a low function as an organic semiconductor.

A polymer having a porphyrin structure introduced is also known. J. Polym. Sci. Part A; Polym. Chem, 43 (2005) 2997 (Non-Patent Document 1) discloses that 5-[4-(2-methacryloyloxyethoxycarbonyl)phenyl]-10,15,20-triphenylporphinato platinum (II) is copolymerized with isobutyl methacrylate and 2,2,2-trifluoroethyl methacrylate to give a polymer having a porphyrin structure introduced in a side chain thereof and that the polymer is embedded in an oxygen-permeable polymer to give a pressure-sensitive element consisting of a light-emitting molecule.

Such a polymer has a sufficiently long distance between side chains thereof in order to prevent stacking formation of the side chains. Thus the polymer also has an insufficient function as an organic semiconductor and needs a higher degree of electron transfer. For that reason, the polymer is unsuitable for the purpose of an organic transistor or an organic solar cell.

Japanese Patent Application Laid-Open Publication No. 2013-155229 (JP-2013-155229A, Patent Document 2) discloses a conjugated polymer having, in a main chain thereof, an aromatic ring and a 5-membered heterocycle containing a heteroatom selected from group 14 to 16 elements.

Japanese Patent Application Laid-Open Publication No. 2013-185009 (JP-2013-185009A, Patent Document 3) discloses a conjugated polymer having, in a main chain thereof, an aromatic ring and a 5-membered heterocycle containing a heteroatom selected from a group 16 element.

These conjugated polymers, which have a high conductivity (carrier mobility) in spite of a high molecular weight thereof, are useful as an organic semiconductor. The conjugated polymers, however, have limited light absorption wavelength range and limited light absorption characteristics. For an organic solar cell or other uses, it is necessary to develop an organic conjugated polymer having a high absorbance in a wide wavelength range and an excellent photoelectric conversion efficiency. Moreover, the conjugated polymers have a limited emission wavelength range and are thus of a limited use as an electronic device.

### CITATION LIST

### Patent Literature

Patent Document 1: JP-2011-162575A (Claims and Examples)
Patent Document 2: JP-2013-155229A (Claims and Examples)
Patent Document 3: JP-2013-185009A (Claims and Examples)

### Non-Patent Literature

Non-Patent Document 1: J. Polym. Sci. Part A; Polym. Chem, 43 (2005) 2997 (ABSTRACT)

### SUMMARY OF INVENTION

### Technical Problem

It is therefore an object of the present invention to provide a novel organic heteropolymer having a high absorbance in a wide wavelength range and an excellent photoelectric conversion efficiency and being useful for forming an electronic device such as a solar cell, and a process for producing the organic heteropolymer.

Another object of the present invention is to provide a novel organic heteropolymer having a wide emission wavelength range and being useful as a sensitizer (a sensitizing dye) of an electronic device such as a photoelectric conversion element, and a process for producing the organic heteropolymer.

It is still another object of the present invention to provide a novel organic heteropolymer having a high conductivity (carrier mobility) and being useful for forming a polymeric organic semiconductor, and a process for producing the organic heteropolymer.

### Solution to Problem

The inventors of the present invention made intensive studies to achieve the above objects and finally found the following: that the reaction of a polymer precursor having a titanacyclopentadiene skeleton in a main chain thereof and two different halides with different heteroatoms achieves efficient synthesis of a novel organic heteropolymer having different 5-membered heterocycles with different kinds of heteroatoms in a main chain thereof; that the novel organic heteropolymer has a high absorbance in a wide wavelength range and excellent photoelectric conversion efficiency and conductivity and is useful for forming an organic semiconductor; and that the organic heteropolymer has a wide emission wavelength range and excellent light emission characteristics. The present invention was accomplished based on the above findings.

That is, an aspect of the present invention provides an organic heteropolymer having a constitutional unit represented by the following formula (1) and a constitutional unit represented by the following formula (2), and being a copolymeric heteropolymer.

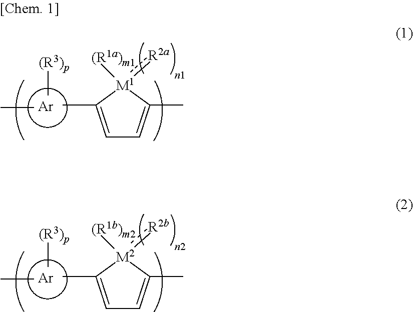

In the formulae, M¹ and M² each represent a heteroatom selected from the group consisting of a group 8 element, a group 9 element, a group 10 element, a group 14 element, a group 15 element, and a group 16 element of the Periodic Table, and M¹ and M² are different in group from each other; M¹ and M² each have a valence v of 2 to 6; R^{1a} and R^{1b} are the same or different and each represent a halogen atom, an alkyl group, a cycloalkyl group, an aryl group, or a heteroaryl group; R^{2a} and R^{2b} are the same or different and each represent a halogen atom, an alkyl group, a cycloalkyl group, an aryl group, a heteroaryl group, a univalent (or monovalent) or bivalent (or divalent) heteroatom selected from the group consisting of a group 16 element and a group 11 element of the Periodic Table, or a metal atom forming a complex with a ligand;

[symbol]

[Chem. 2]

represents a single bond or a double bond; m1, m2, n1, and n2 each denote 0 or 1; a ring Ar represents an aromatic ring; R³ represents a straight- or branched-chain alkyl group, a straight- or branched-chain alkoxy group, or a straight- or branched-chain alkylthio group; and p denotes 0 or an integer of 1 to 3.

The organic heteropolymer may comprise a random copolymer. The ratio (molar ratio) of the constitutional unit represented by the above formula (1) relative to the constitutional unit represented by the above formula (2) may be about 99/1 to 1/99 in the former/the latter.

The constitutional units of the organic heteropolymer may also be represented by the following formula (3) and the following formula (4):

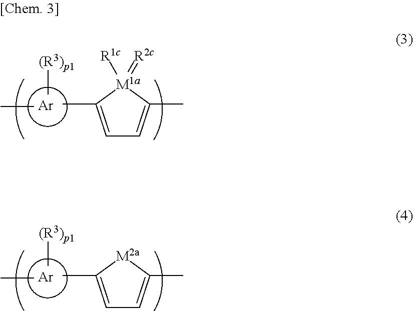

wherein M^{1a} represents a heteroatom selected from a group 15 element of the Periodic Table; M^{2a} and R^{2c} each represent a heteroatom selected from a group 16 element of the Periodic Table; R^{1c} represents an alkyl group, an aryl group, or a heteroaryl group; p1 denotes an integer of 1 to 3; and the ring Ar and R³ have the same meanings as defined above.

The ring Ar may be a ring represented by the following formula (5):

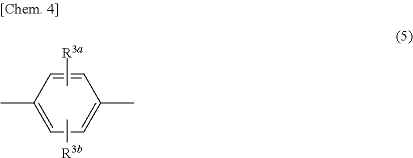

wherein R^{3a} and R^{3b} are the same or different and each represent a straight- or branched-chain C₄₋₁₂alkyl group, a straight- or branched-chain C₄₋₁₂alkoxy group, or a straight- or branched-chain C₄₋₁₂alkylthio group.

Another aspect of the present invention provides a process for producing the organic heteropolymer. Specifically, the organic heteropolymer may be produced by allowing a polymer having a constitutional unit represented by the following formula (8) to react with a halide represented by the following formula (9) and a halide represented by the following formula (10).

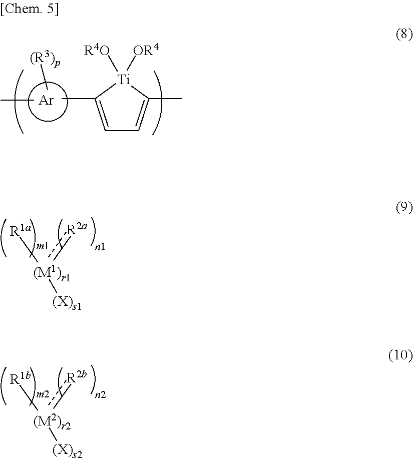

In the formulae, R⁴ represents an alkyl group; X represents a halogen atom; r1 and r2 each denote an integer of 1 to 3; s1 and s2 each denote an integer of 1 to 6; M¹ has a valence v¹ of 2 to 6; M² has a valence v² of 2 to 6; the valences v¹ and v² each satisfy the following

equations: v¹=m1+n1+s1, v²=m2+n2+s2;

[symbol]

[Chem. 6]

represents a single bond or a double bond; provided that, when [symbol] is a double bond, the valences v¹ and v² each satisfy the following equations: v¹=m1+2×n1+s1, v²=m2+2×n2+s2. M¹, M², R^{1a}, R^{1b}, R^{2a}, R^{2b}, R³, the ring Ar, m1, m2, n1, n2, and p have the same meanings as defined above.

The organic heteropolymer may also be produced by allowing a polymer represented by the above formula (8) to react with a halide represented by the following formula (9A) and a halide represented by the following formula (10A):

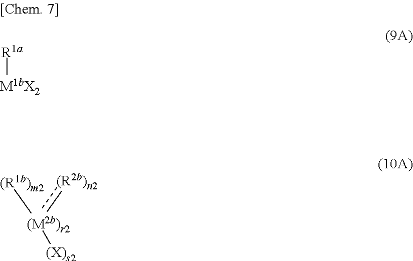

wherein M^{1b} represents a heteroatom selected from a group 15 element of the Periodic Table; M^{2b} represents a heteroatom selected from the group consisting of a group 8 element, a group 9 element, a group 10 element, a group 14 element, and a group 16 element of the Periodic Table; M^{2b} has a valence v^{2b} of 2 to 6; the valence v^{2b} satisfies the following equation: v^{2b}=m2+n2+s2;

[symbol]

[Chem. 8]

represents a single bond or a double bond; provided that, when [symbol] is a double bond, the valence v^{2b} satisfies the following equation: v^{2b}=m2+2×n2+s2; R^{1a}, R^{1b}, R^{2b}, r2, s2, m2, n2, and X have the same meanings as defined above;

to give an organic heteropolymer having a constitutional unit represented by the following formula (1A) and a constitutional unit represented by the following formula (2A):

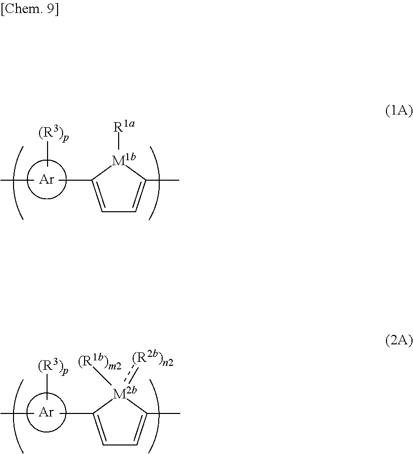

wherein

[symbol]

[Chem. 10]

represents a single bond or a double bond; M^{1b}, M^{2b}, R^{1a}, R^{1b}, R^{2b}, R³, the ring Ar, m2, n2, and p have the same meanings as defined above; and

allowing the organic heteropolymer to react with a compound represented by the following formula (11) or and elemental substance represented by the following formula (12):

[Chem. 11]

L-R^{2a1} (11)

R^{2a2} (12)

wherein R^{2a1} represents a metal atom forming a complex with a ligand; L represents a leaving group; and R^{2a2} represents an elemental substance selected from a group 16 element of the Periodic Table.

The organic heteropolymer is soluble in an organic solvent. Thus a further aspect of the present invention provides a composition containing the organic heteropolymer and an organic solvent. The composition is useful for forming an organic semiconductor.

A further aspect of the present invention provides an organic semiconductor comprising the organic heteropolymer, and an electronic device containing the organic heteropolymer. A further aspect of the present invention provides an electronic device containing the organic semiconductor. The electronic device may, for example, be one member selected from the group consisting of a photoelectric conversion element, a switching device, and a rectifier.

As used herein, -M¹-R^{2a} indicates a state in which R^{2a} is singly bonded to the heteroatom M¹, and -M¹=R^{2a} indicates a state in which R^{2a} is doubly bonded to the heteroatom M¹. As used herein, -M²-R^{2b} indicates a state in which R^{2b} is singly bonded to the heteroatom M², and -M²=R^{2b} indicates a state in which R^{2b} is doubly bonded to the heteroatom M².

### Advantageous Effects of Invention

The organic heteropolymer of the present invention, of which the main chain has a conjugated system having a conjugated bond of the aromatic ring and the different 5-membered heterocycles with different heteroatoms, has a high conductivity (carrier mobility) and semiconductor characteristics. In particular, the organic heteropolymer of the present invention contains different kinds of heterocycles in a molecule thereof and shows a high absorbance in a wide wavelength range, and thus the organic heteropolymer has an improved photoelectric conversion efficiency. The organic heteropolymer is useful for forming an organic semiconductor and is usable as an electronic device such as a solar cell. The organic heteropolymer is also useful as a sensitizing dye (a sensitizer) of an electronic device such as a photoelectric conversion element. Further, the organic heteropolymer of the present invention has a wide emission wavelength range and excellent light emission characteristics. Thus the organic heteropolymer is also useful as a photoelectric device material.

### BRIEF DESCRIPTION OF DRAWINGS

FIG. 1 is a graph showing ultraviolet-visible light absorption spectra in Examples and Comparative Examples.

FIG. 2 is a graph showing emission spectra in Examples and Comparative Examples.

FIG. 3 is a graph showing electric current density-potential characteristics of a dye-sensitized solar cell having a polymer obtained in Example 1.

### DESCRIPTION OF EMBODIMENTS

### Organic Heteropolymer

The organic heteropolymer of the present invention is a copolymer having the constitutional units represented by the above formulae (1) and (2). The copolymer may be a random copolymer, an alternating copolymer, or a block copolymer. In particular, the random copolymer is preferred.

In the above formulae (1) and (2), M¹ and M² each represent a heteroatom selected from the group consisting of a group 8 element (e.g., Fe, Ru, Os), a group 9 element (e.g., Co, Rh, Ir), a group 10 element (e.g., Ni, Pd, Pt), a group 14 element (e.g., Si, Ge, Sn, Pb), a group 15 element (e.g., N, P, As, Sb, Bi), and a group 16 element (e.g., S, Se, Te) of the Periodic Table, and M¹ and M² are different in group from each other. Among these heteroatoms M¹ and M², n a group 8 element of the Periodic Table, for example, Fe or Ru, particularly Ru, is preferred; in a group 9 element, for example, Co or Rh, particularly Rh, is preferred; in a group 10 element, for example, Ni or Pd, particularly Ni, is preferred; in a group 14 element, for example, Si, Ge, or Sn, particularly Sn, is preferred; in a group 15 element, for example, P, As, Sb, or Bi, particularly P, is preferred; and in a group 16 element, for example, S, Se, or Te, particularly S, is preferred.

The different heteroatoms represented by M¹ and M² are selected from different groups. For example, M¹ may be at least one heteroatom selected from the group consisting of the group 8 to 10 elements of the Periodic Table, M² may be at least one heteroatom selected from the group consisting of the group 14 to 16 elements of the Periodic Table. M¹ may be at least one heteroatom selected from the group 15 element of the Periodic Table, and M² may be at least one heteroatom selected from the group consisting of the group 8 to 10 and 14 to 16 elements of the Periodic Table. An organic heteropolymer containing at least one of the group 8 to 10 elements of the Periodic Table as the heteroatom has a high absorbance and an absorption in a long-wavelength range due to unique charge transfer transition (e.g., MLCT transition). This probably causes the organic heteropolymer to have an excellent photoelectric conversion efficiency in addition to a high conductivity (carrier mobility).

These heteroatoms each have a valence v, depending on the kind of the heteroatom, of 2 to 6, preferably 2 to 5. The group 8 element of the Periodic Table (e.g., Ru, Fe) usually has a valence of 2 to 4, the group 9 element (e.g., Co, Rh) usually has a valence of 2 or 3, the group 10 element (e.g., Ni, Pd) usually has a valence of 2 to 4, the group 14 element (e.g., Sn) usually has a valence of 4, the group 15 element of the Periodic Table (e.g., P) usually has a valence of 3 to 5, and the group 16 element of the Periodic Table (e.g., S, Se, Te) usually has a valence of 2 to 5.

Examples of the halogen atoms represented by R^{1a}, R^{1b}, R^{2a}, and R^{2b} may include fluorine atom, chlorine atom, bromine atom, and iodine atom, usually chlorine atom or bromine atom.

The alkyl groups represented by R^{1a}, R^{1b}, R^{2a}, and R^{2b} may include, for example, a straight- or branched-chain C₁₋₆alkyl group such as methyl group, ethyl group, propyl group, isopropyl group, butyl group, isobutyl group, s-butyl group, or t-butyl group. A preferred alkyl group includes a straight- or branched-chain C₁₋₄alkyl group (e.g., a C₁₋₂alkyl group).

Examples of the cycloalkyl groups represented by R^{1a}, R^{1b}, R^{2a}, and R^{2b} may include a C₃₋₁₀cycloalkyl group such as cyclopropyl group, cyclobutyl group, cyclopentyl group, cyclohexyl group, cycloheptyl group, or cyclooctyl group. A preferred cycloalkyl group includes a C₅₋₈cycloalkyl group.

Examples of the aryl groups represented by R^{1a}, R^{1b}, R^{2a}, and R^{2b} may include a C₆₋₁₂aryl group which may have a C₁₋₄alkyl group as a substituent, for example, phenyl group, tolyl group, xylyl group, and naphthyl group. A preferred aryl group includes a C₆₋₁₀aryl group such as phenyl group.

The heteroaryl groups represented by R^{1a}, R^{1b}, R^{2a}, and R^{2b} may include, for example, a 5-membered heterocyclic group containing at least one heteroatom selected from the group consisting of a sulfur atom, a nitrogen atom, and an oxygen atom (such as thienyl group, pyrrolyl group, imidazolyl group, or furyl group), a 6-membered heterocyclic group containing at least one heteroatom selected from the group consisting of a sulfur atom, a nitrogen atom, and an oxygen atom (such as pyridyl group or pyrazinyl group).

R^{2a} and R^{2b} may be a univalent or bivalent heteroatom (heterometal atom), for example, a heteroatom (heterometal atom) selected from the group consisting of a group 16 element of the Periodic Table (e.g., O, S, Se, Te) and a group 11 element of the Periodic Table (e.g., Cu, Ag, Au). Among the heteroatoms (heterometal atoms) represented by R^{2a} and R^{2b}, a group 16 element of the Periodic Table (e.g., O, S, Se, and Te, particularly S, Se) and a group 11 element of the Periodic Table (e.g., Ag and Au, particularly Au) are preferred. Among these heteroatoms (heterometal atoms), the group 16 element of the Periodic Table is bonded to the heteroatom M¹ or M² to form a double bond, and the group 11 element of the Periodic Table is bonded to the element (heteroatom) M¹ or M² to form a single bond. The heteroatom (heterometal atom) (for example, the group 11 element of the Periodic Table) may form a complex (a complex with a ligand such as a halogen atom such as chlorine or bromine, oxygen atom, OH (hydroxo), H₂O (aquo), CO, CN, an alkoxy group such as methoxy group, acetyl group, methoxycarbonyl (acetato) group, acetylacetonato group, cyclopentadienyl group, pyridine, or phosphine) or may form a halide (a halide such as a chloride or a bromide).

R^{1a} and R^{1b} are practically a straight- or branched-chain C₁₋₄alkyl group such as methyl group (for example, a C₁₋₂alkyl group), a C₆₋₁₀aryl group such as phenyl group. R^{2a} and R^{2b} are practically a straight- or branched-chain C₁₋₄alkyl group such as methyl group (for example, a C₁₋₂alkyl group), a C₆₋₁₀aryl group such as phenyl group, a heteroatom (for example, S, Se, Te, and O, particularly S) doubly bonded to the heteroatom M¹ or M².

R^{1a}, R^{1b}, R^{2a} and R^{2b} may be the same group or atom or may be different from one another.

The subscripts m1, m2, n1, and n2 each denote 0 or 1. According to the valences of the heteroatoms M¹ and M², these subscripts may satisfy the following equation: m1=n1 (or m2=n2)=0 or may satisfy the following equation: m1+n1 (or m2+n2)=1 or 2.

The aromatic ring represented by the ring Ar may include an arene ring such as benzene ring or naphthalene ring, a heteroarene ring such as thiophene ring, pyrrole ring, imidazole ring, fran ring, pyridine ring, or pyrazine ring, a bisarene ring such as fluorene ring, biphenyl ring, or binaphthyl ring, and a bisheteroarene ring such as bipyridine ring. Representative examples of the aromatic ring Ar may include a C₆₋₁₂arene ring such as benzene ring or naphthalene ring (in particular, a C₆₋₁₀arene ring), a 5- or 6-membered heteroarene ring such as thiophene ring or pyridine ring, and a bisarene ring such as fluorene ring, biphenyl ring, or binaphthyl ring. The aromatic ring Ar is practically benzene ring, naphthalene ring, fluorene ring (in particular, benzene ring).

R³ is useful for solubilizing the organic heteropolymer in a solvent. The alkyl group represented by R³ may include, for example, a straight- or branched-chain alkyl group such as methyl group, ethyl group, propyl group, isopropyl group, butyl group, isobutyl group, s-butyl group, t-butyl group, pentyl group, neopentyl group, hexyl group, heptyl group, octyl group, 2-ethylhexyl group, nonyl group, decanyl group, undecanyl group, or dodecanyl group. The alkyl group is usually a straight- or branched-chain C₄₋₁₆alkyl group, preferably a straight- or branched-chain C₆₋₁₂alkyl group, and more preferably a straight- or branched-chain C₆₋₁₀alkyl group.

The alkoxy group represented by R³ may include a straight- or branched-chain alkoxy group corresponding to the alkyl group described above, for example, a straight- or branched-chain C₄₋₁₆alkoxy group such as hexyloxy group, octyloxy group, or 2-ethylhexyloxy group, preferably a straight- or branched-chain C₆₋₁₂alkoxy group, and more preferably a straight- or branched-chain C₆₋₁₀alkoxy group.

The alkylthio group represented by R³ may include a straight- or branched-chain alkylthio group corresponding to the alkyl group described above, for example, a straight- or branched-chain C₄₋₁₆alkylthio group such as hexylthio group, octylthio group, or 2-ethylhexylthio group, preferably a straight- or branched-chain C₆₋₁₂alkylthio group, and more preferably a straight- or branched-chain C₆₋₁₀alkylthio group.

R³ is practically an alkoxy group. The subscript p denotes 0 or an integer of 1 to 3, usually an integer of 1 to 3 (e.g., 2).

The substitution position of R³ with respect to the ring Ar is not limited and can be selected according to the kind of the ring Ar, the position of bonding site of the ring Ar, and the number p of substituents R³. For example, in a case where the ring Ar is benzene ring, the substitution position(s) of R³ may be any one of 2-, 3-, 4-, 5-, and 6-positions, or may be a plurality of positions such as 2,3-positions, 2,5-positions, or 2,6-positions. For thiophene ring, the substitution position(s) may be 3-position or 3,4-positions. For fluorene ring, the substitution position(s) may be 9,9-positions; for 1,1′-binaphthyl ring, the substitution position(s) may be 2,2′-positions or other positions; and for 1,2′-binaphthyl ring, the substitution position(s) may be 2,1′-positions or other positions.

A preferred unit containing the ring Ar may include a substituted benzene ring and a substituted fluorene ring, in particular, a di-substituted benzene ring (1,4-phenylene group) represented by the following formula (5):

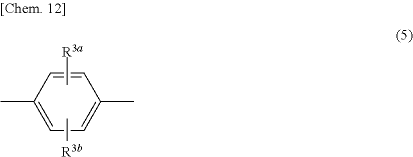

wherein R^{3a} and R^{3b} are the same or different and each represent a straight- or branched-chain C₄₋₁₂alkyl group, a straight- or branched-chain C₄₋₁₂alkoxy group, or a straight- or branched-chain C₄₋₁₂alkylthio group.

Preferred R^{3a} and R^{3b} include the preferred alkyl group, alkoxy group, and alkylthio group as described in the paragraph of the substituent R³. R^{3a} and R^{3b} usually have an alkyl chain with about 6 to 12 (e.g., about 6 to 10) carbon atoms. The substitution positions of R^{3a} and R^{3b} may be 2,3-positions, 2,5-positions, or 2,6-positions, practically 2,5-positions.

The ratio of the constitutional unit represented by the above formula (1) relative to the constitutional unit represented by the above formula (2) can be selected as appropriate according to the types of the constitutional units. For example, the ratio of the former/the latter (molar ratio) may be about 99/1 to 1/99 (e.g., about 90/10 to 10/90), preferably about 80/20 to 20/80 (e.g., about 70/30 to 30/70), and more preferably about 60/40 to 40/60.

Representative organic heteropolymer of the present invention may include a copolymer having a constitutional unit represented by the following formula (3) and a constitutional unit represented by the following formula (4):

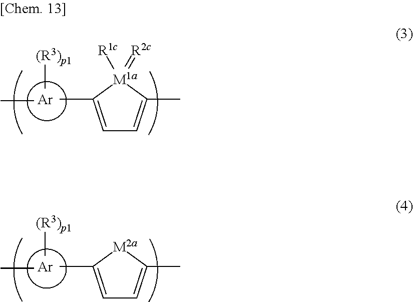

wherein M^{1a} represents a heteroatom selected from a group 15 element of the Periodic Table; M^{2a} and R^{2c} each represent a heteroatom selected from a group 16 element of the Periodic Table; R^{1c} represents an alkyl group, an aryl group, or a heteroaryl group; p1 denotes an integer of 1 to 3; and the ring Ar and R³ have the same meanings as defined above.

The ratio of the constitutional units represented by the above formulae (3) and (4) is the same as the ratio of the constitutional units represented by the above formulae (1) and (2).

The heteroatom M^{1a} can be selected from the group 15 element of the Periodic Table (for example, P, As, Sb, Bi). In particular, P is preferred. The heteroatoms M^{2a} and R^{2c} can be selected from the group 16 element of the Periodic Table (for example, S, Se, Te). In particular, S is preferred.

R^{1c} may include the alkyl group, the aryl group, or the heteroaryl group as described in the above-mentioned R^{1a} and R^{1b}. In particular, the aryl group (e.g., phenyl group R^{1c} is preferred.

The subscript p1 is an integer of 1 to 3 and preferably an integer of 1 to 2 (in particular 2).

The organic heteropolymer of the present invention is characterized by a high conductivity (carrier mobility) in spite of a relatively high molecular weight thereof. The organic heteropolymer is not limited to particular molecular weights. For example, the organic heteropolymer may have a number-average molecular weight Mn measured by gel permeation chromatography (GPC) of about 1×10³ to 1×10⁵, preferably 2×10³ to 5×10⁴, more preferably 3×10³ to 2.5×10⁴ in terms of polystyrene. The organic heteropolymer may have a molecular weight distribution (weight-average molecular weight Mw/number-average molecular weight Mn) of not more than 5, for example, about 1.5 to 4.5, preferably about 2.0 to 4.0, and more preferably about 2.5 to 3.5.

The organic heteropolymer is practically a straight-chain polymer, although the organic heteropolymer may have a branched-chain structure if necessary.

The organic heteropolymer of the present invention has a conjugated system formed in a main chain thereof, and the conjugated system has a conjugated bond of an aromatic ring and different 5-membered heterocycles with different heteroatoms. The organic heteropolymer, which contains different kinds of heterocycles in a molecule thereof, shows a high absorbance in a wide wavelength range, and thus has an improved photoelectric conversion efficiency. Further, the organic heteropolymer has a wide emission wavelength range and excellent light emission characteristics.

The organic heteropolymer has the 5-membered heterocycles in a main-chain skeleton thereof and thus has a weak autoagglutination. In addition, the formation of the conjugated system of the aromatic ring and the 5-membered heterocycles maintains a unique electronic state due to hydrocarbon-heteroatom bonds throughout the main chain. Thus the organic heteropolymer has excellent semiconductor characteristics.

Further, the aromatic ring (arene ring) may have a side chain such as an alkyl group, and the organic heteropolymer having the aromatic ring with such a side chain has both an improved solubility and a solvent solubility. Thus such an organic heteropolymer allows easy film formation by coating. Furthermore, the organic heteropolymer has a high stability and is stable to water or temperature (such as a room temperature).

The organic heteropolymer is formed into a structural film that allows easy intermolecular electron transfer probably due to stacking between main chains after film formation. If the polymer has alkyl groups, the alkyl chains, which are probably arranged parallel with the stacking direction (vertical direction), do not inhibit stacking. Probably for that reason, the resulting film effectively functions as an organic semiconductor.

[Process for Producing Organic Heteropolymer]

The organic heteropolymer of the present invention can be synthesized from a titanacyclopentadiene-skeleton-containing polymer consisting of a constitutional unit represented by the following formula (8). Specifically, this polymer is useful as a precursor of the organic heteropolymer. The polymer represented by the following formula (8) can be obtained by the reaction of a diethynylarene compound represented by the following formula (6) and a low-valent titanium complex represented by the following formula (7):

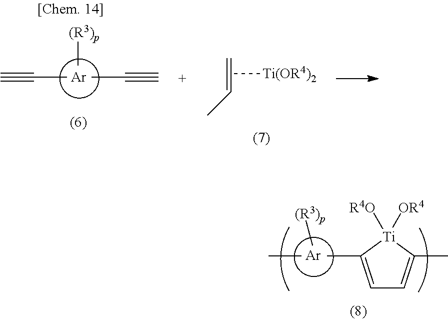

wherein R⁴ represents an alkyl group; and R³, the ring Ar, and p have the same meanings as defined above.

The alkyl group represented by R⁴ may include, for example, a straight- or branched-chain C₁₋₆alkyl group such as methyl group, ethyl group, propyl group, isopropyl group, butyl group, isobutyl group, s-butyl group, or t-butyl group. In particular, the alkyl group is practically a branched alkyl group, for example, isopropyl group.

The diethynylarene compound represented by the above formula (6) may in include, for example, a diethynyldialkoxybenzene such as 1,4-diethynyl-2,5-dioctyloxybenzene or 1,4-diethynyl-2,5-di(2-ethylhexyloxy)benzene; a diethynylalkylthiophene such as 2,5-diethynyl-3-dodecanylthiophene; a diethynyldialkylfluorene such as 2,7-diethynyl-9,9-dioctylfluorene; a diethynyldioctyloxybinaphthyl such as 6,6′-diethynyl-2,2′-dioctyloxy-1,1′-binaphthyl; and a diethynyldialkylbinaphthyl such as 6,6′-diethynyl-2,2′-dioctyl-1,1′-binaphthyl.

The low-valent titanium complex represented by the above formula (7) can be produced by allowing a tetraalkoxytitanium (such as tetraisopropoxytitanium (Ti(OPrⁱ)₄)) to react with an alkylmagnesium halide (such as isopropylmagnesium chloride (ⁱPrMgCl)). Thus the polymer represented by the above formula (8) may be produced by the reaction of the diethynylarene compound represented by the formula (6), the tetraalkoxytitanium, and the alkylmagnesium halide. The amount of the alkylmagnesium halide relative to 1 mol of the tetraalkoxytitanium is about 1.5 to 2.5 mol. The reaction can usually be carried out with stirring in an inactive solvent (such as diethyl ether, tetrahydrofuran, or cyclopentyl methyl ether) under an inactive atmosphere [such as nitrogen or a rare gas (in particular, argon)]. The reaction temperature may be about −100° C. to −20° C. (e.g., about −80° C. to −40° C.). The reaction time may be, for example, about 1 to 48 hours, usually 2 to 36 hours, preferably about 3 to 24 hours.

(Reaction Step 1)

The organic heteropolymer of the present invention may be produced by the reaction of the polymer having the constitutional unit represented by the above formula (8), a halide represented by the following formula (9), and a halide represented by the following formula (10).

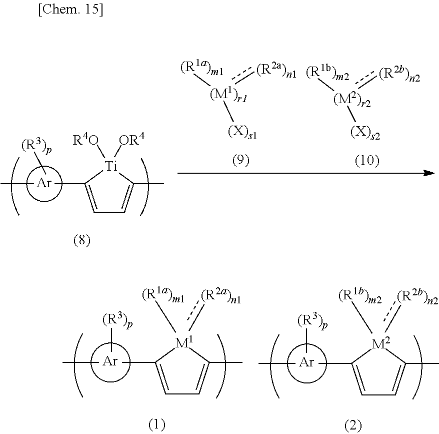

In the formula, X represents a halogen atom; M¹ has a valence v¹ of 2 to 6; M² has a valence v² of 2 to 6; r1 and r2 each denote an integer of 1 to 3; s1 and s2 each denote an integer of 1 to 6; v¹ and v² each satisfy the following equations: v¹=m1+n1+s1, v²=m2+n2+s2;

[symbol]

[Chem. 16]

represents a single bond or a double bond; provided that, when [symbol] is a double bond, v¹ and v² each satisfy the following equations: v¹=m1+2×n1+s1, v²=m2+2×n2+s2. M¹, M², R^{1a}, R^{1b}, R^{2a}, R^{2b}, R³, R⁴, the ring Ar, m1, m2, n1, n2, and p have the same meanings as defined above.

In the above formulae (9) or (10), the halogen atom represented by X may include chlorine atom, bromine atom, and iodine atom, practically chlorine atom or bromine atom.

In the above formulae (9) and (10), the heteroatoms M¹ and M² may include elements exemplified in the above formulae (1) and (2). The valence v¹ of M¹ and the valence v² of M², each of which depends on the kind of the heteroatom, may be 2 to 6 and preferably 2 to 5. The subscripts r1 and r2, which represent the number of heteroatoms M¹ and the number of heteroatoms M², respectively, may be an integer of 1 to 3. For example, r1 and r2 are practically 1 or 2 for a halide which satisfies the equation: m1=n1=0 or m2=n2=0; r1 and r2 are practically 1 for a halide which satisfies the equation: m1+n1 or m2+n2=1 or 2. The subscripts s1 and s2, each of which represents the number of halogen atoms X, may be an integer of 1 to 6. The relation between the valences v¹ and v² and each coefficient is expressed in the equations: v¹=m1+n1+s1 and v²=m2+n2+s2, provided that, when the bonding state between M¹ and M² and R^{2a} or R^{2b} is -M¹=R^{2a} or -M²=R^{2b}, the relation is expressed in the equation: v¹=m1+2×n1+s1 or v²=m2+2×n2+s2.

The halide represented by the above formula (9) or (10) may include halides represented by the following formulae:

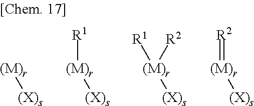

wherein M represents either M¹ or M² described above; R¹ represents either R^{1a} or R^{1b} described above; R² represents either R^{2a} or R^{2b} described above; r denotes an integer of 1 to 3; s denotes an integer of 1 to 6; and X has the same meaning as defined above.

The halide represented by the above formula (9) or (10) in which the heteroatom M¹ or M² is a group 8 element of the Periodic Table may include, for example, a halide such as iron dichloride (FeCl₂), iron trichloride (FeCl₃), ruthenium trichloride (RuCl₃), or ruthenium tetrachloride (RuCl₄); an alkyl (or aryl) metal halide such as an alkyl dichlororuthenium or an aryl dichlororuthenium [hereinafter, these compounds may be referred to as an alkyl (or aryl) dichlororuthenium]; and a dialkyl (or diaryl) metal halide such as a dialkyl dichlororuthenium or a diaryl dichlororuthenium [hereinafter, these compounds may be referred to as a dialkyl (or diaryl) dichlororuthenium].

The halide represented by the above formula (9) or (10) in which the heteroatom M¹ or M² is a group 9 element of the Periodic Table may include, for example, a halide such as cobalt dichloride (CoCl₂) or rhodium trichloride (RhCl₃); and an alkyl (or aryl) metal halide such as an alkyl (or aryl) dichlororhodium.

The halide represented by the above formula (9) or (10) in which the heteroatom M¹ or M² is a group 10 element of the Periodic Table may include, for example, a halide such as nickel dichloride (NiCl₂) or palladium dichloride (PdCl₂); and a dialkyl (or diaryl) metal halide such as a dialkyl (or diaryl) dichloropalladium.

The halide represented by the above formula (9) or (10) in which the heteroatom M¹ or M² is a group 14 element of the Periodic Table may include, for example, a halide such as tin dichloride (SnCl₂) or tin tetrachloride (SnCl₄); and a dialkyl (or diaryl) metal halide such as a dialkyl (or diaryl) dichlorosilane or a dialkyl (or diaryl) dichlorotin.

The halide represented by the above formula (9) or (10) in which the heteroatom M¹ or M² is a group 15 element of the Periodic Table may include, for example, a halide such as antimony trichloride (SbCl₃); an alkyl (or aryl) metal halide such as an alkyl (or aryl) dichlorophosphine or an alkyl (or aryl) dichloroantimony; a dialkyl (or diaryl) metal halide such as a dialkyl (or diaryl) dichlorophosphine; and a halide such as phosphoryl chloride.

The halide represented by the above formula (9) or (10) in which the heteroatom M¹ or M² is a group 16 element of the Periodic Table may include, for example, a halide such as disulfur dichloride (S₂Cl₂), diselenium dichloride (Se₂Cl₂), tellurium dichloride (TeCl₂), selenium tetrachloride (SeCl₄), or tellurium tetrachloride (TeCl₄); an alkyl (or aryl) metal halide such as an alkyl (or aryl) dichlorotellurium; a dialkyl (or diaryl) metal halide such as a dialkyl (or diaryl) dichloroselenium; and a halide such as thionyl chloride.

The halide with the heteroatom M¹ and the halide with the heteroatom M² different in group from M¹ among these halides can be allowed to react with the polymer represented by the above formula (8) to give an organic heteropolymer, of the present invention, with different kinds of heteroatoms (M¹ and M²) having substituent(s) which may be the same or different.

A representative organic heteropolymer of the present invention, for example, an organic heteropolymer having constitutional units represented by the above formulae (1) and (2) in which m1=n1=1, the bonding state between M¹ and R^{2a} is -M¹=R^{2a}, and m2=n2=0 can be obtained by the reaction of the polymer represented by the above formula (8), the halide of the group 15 element of the Periodic Table [for example, an alkyl (or aryl) dichlorophosphine], and the halide of the group 16 element of the Periodic Table [for example, disulfur dichloride (S₂Cl₂) or diselenium dichloride (Se₂Cl₂)].

The ratio of the halide represented by the above formula (9) relative to the halide represented by the above formula (10) can suitably be selected according to the ratio of the constitutional unit represented by the above formula (1) relative to the constitutional unit represented by the above formula (2), and may, for example, be about 99/1 to 1/99 (e.g., about 90/10 to 10/90), preferably about 80/20 to 20/80 (e.g., about 70/30 to 30/70), and more preferably about 60/40 to 40/60 in the former/the latter (molar ratio).

In the reaction, the total amount of the halides represented by the above formulas (9) and (10) may be about 0.8 to 2 mol (e.g., about 1 to 1.5 mol) relative to 1 mol of titanium atom Ti in the polymer represented by the above formula (10).

For the reaction, one of the halides represented by the above formulae (9) and (10) may be allowed to react with the polymer represented by the above formula (8) to give a product which is then allowed to react with the other halide, or both of the halides may simultaneously be allowed to react with the polymer.

The reaction can usually be carried out with stirring in an inactive solvent (such as diethyl ether, tetrahydrofuran, or cyclopentyl methyl ether) under an inactive atmosphere [such as nitrogen or a rare gas (in particular, argon)]. The reaction may be carried out at a temperature of about −80° C. to 30° C. (e.g., about −60° C. to a room temperature). The reaction time may be, for example, about 1 to 48 hours, usually about 2 to 36 hours, and preferably about 3 to 24 hours. After the reaction is completed, the resulting product may be subjected to a conventional separation and purification means, such as concentration, decantation, reprecipitation, or chromatography, to give a desired organic heteropolymer.

(Reaction Step 2)

The organic heteropolymer of the present invention may be produced by allowing the polymer having the constitutional unit represented by the above formula (8) to react with a halide represented by the formula (9A) and a halide represented by the formula (10A) to give a polymer having a constitutional unit represented by the formula (1A) and a constitutional unit represented by the formula (2A), and allowing the resulting polymer to react with a compound represented by the formula (11) to give an organic heteropolymer having a constitutional unit represented by the formula (1B) and a constitutional unit represented by the formula (2A). The organic heteropolymer of the present invention may also be produced by allowing the polymer having the constitutional unit represented by the formula (1A) and the constitutional unit represented by the formula (2A) to react with an elemental substance represented by the formula (12) to give an organic heteropolymer having a constitutional unit represented by the formula (1C) and a constitutional unit represented by the formula (2A).

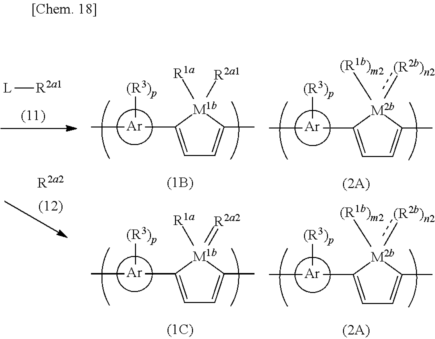

In the formulae, M^{1b} represents a heteroatom selected from a group 15 element of the Periodic Table; M^{2b} represents a heteroatom selected from the group consisting of a group 8 element, a group 14 element, and a group 16 element of the Periodic Table; M^{2b} has a valence v^{2b} of 2 to 6; the valence v^{2b} satisfies the following equation: v^{2b}=m2+n2+s2;

[symbol]

[Chem. 19]

represents a single bond or a double bond; provided that, when [symbol] is a double bond, the valence v^{2b} satisfies the following equation: v^{2b}=m2+2×n2+s2. R^{2a1} represents a metal atom forming a complex with a ligand; L represents a leaving group; R^{2a2} represents an elemental substance selected from a group 16 element of the Periodic Table; and R^{1a}, R^{1b}, R^{2b}, R³, R⁴, the ring Ar, X, r2, s2, m2, n2, and p have the same meanings as defined above.

The heteroatom M^{1b} includes the group 15 element of the Periodic Table (e.g., P). The heteroatom M^{2b} includes the group 8 element of the Periodic Table (e.g., Fe, Ru), the group 9 element of the Periodic Table (e.g., Co, Rh), the group 10 element of the Periodic Table (e.g., Ni, Pd), the group 14 element of the Periodic Table (e.g., Si, Ge, Sn), and the group 16 element of the Periodic Table (e.g., S, Se, Te). The valence v^{2b} of the heteroatom M^{2b} is 2 to 6 and preferably 2 to 5 and satisfies the following equation: v^{2b}=m2+n2+s2. Provided that, when the bonding state between M^{2b} and R^{2b} is -M^{2b}=R^{2b}, the valence v^{2b} satisfies the following equation: v^{2b}=m2+2×n2+s2.

The halide represented by the above formula (9A) may include, for example, a halide in which the above-exemplified heteroatom is a group 15 element of the Periodic Table [for example, an alkyl (or aryl) dichlorophosphine].

The halide represented by the above formula (10A) may include, for example, a halide in which the above-exemplified heteroatom is a group 8 element of the Periodic Table (e.g., a halide such as iron trichloride or ruthenium trichloride), a halide in which the heteroatom is a group 9 element of the Periodic Table (e.g., a halide such as cobalt dichloride or rhodium trichloride), a halide in which the heteroatom is a group 10 element of the Periodic Table (e.g., a halide such as nickel dichloride), a halide in which the heteroatom is a group 14 element of the Periodic Table (e.g., a dialkyl (or diaryl) metal halide such as a dialkyl (or diaryl) dichlorotin), or a halide in which the heteroatom is a group 16 element of the Periodic Table (e.g., a halide such as thionyl chloride, and a dialkyl (or diaryl) metal halide such as a dialkyl (or diaryl) dichloroselenium).

The organic heteropolymer having the constitutional unit represented by the above formula (1A) and the constitutional unit represented by the above formula (2A) may be synthesized in the same manner as the reaction step 1.

In the above formula (11), R^{2a1} may include a metal atom forming the complex exemplified above (for example, a metal atom selected from a group 11 element of the Periodic Table, particularly gold). The leaving group represented by L may include a ligand coordinated with the metal atom R^{2a1} (e.g., tetrahydrothiophene). The compound represented by the above formula (11) may include, for example, a tetrahydrothiophene chloride complex.

In the above formula (12), examples of the elemental substance R^{2a2} may include sulfur, selenium, and tellurium.

In the reaction, the ratio of the compound represented by the above formula (11) or the simple substance represented by the above formula (12) may be about 1 to 2 mol (e.g., about 1.1 to 1.5 mol) relative to 1 mol of the heteroatom M^{1b} in the above formula (1A).

The reaction may be carried out with stirring in an inactive solvent (such as diethyl ether, tetrahydrofuran, or cyclopentyl methyl ether) under an inactive atmosphere [such as nitrogen or a rare gas (in particular, argon)]. The reaction temperature may usually be a temperature of about 0 to 50° C. (e.g., about 10 to 30° C., particularly about a room temperature). The reaction time and the purification method may be the same conditions as those in the reaction step 1.

The production process of the present invention enables an organic heteropolymer having different 5-membered heterocycles with different kinds of heteroatoms (M¹ and M²) to be synthesized efficiently and simply in a small number of steps. The resulting heteropolymer is useful as an organic semiconductor.

[Use of Organic Heteropolymer]

The main chain of the organic heteropolymer forms a conjugated system (π-conjugated system) of the aromatic ring and the different 5-membered heterocycles with different heteroatoms, and thus the organic heteropolymer has an extremely high electron transfer and semiconductor characteristics. The organic heteropolymer has unique optical characteristics in many cases compared with a polymer consisting of a single constitutional unit, although that reason is not known exactly. Further, the organic heteropolymer which has a long alkyl chain in a side chain thereof is characterized by a high solubility in an organic solvent and a high conductivity (a high semiconductor characteristic). Thus, the present invention also includes a composition (a coating composition) containing the organic heteropolymer and an organic solvent. The composition is useful for forming an organic semiconductor, in particular, for forming a thin film of an organic semiconductor by coating (applying) or other simple methods.

The organic solvent may include, for example, a hydrocarbon (e.g., an aliphatic hydrocarbon such as hexane, an alicyclic hydrocarbon such as cyclohexane, and an aromatic hydrocarbon such as toluene or xylene), a halogenated hydrocarbon (such as chloroform, dichloromethane, or trichloroethane), an ether (e.g., a chain ether such as diethyl ether or diisopropyl ether, and a cyclic ether such as dioxane or tetrahydrofuran), a ketone (such as acetone or methyl ethyl ketone), an ester (such as methyl acetate, ethyl acetate, or butyl acetate), an amide (e.g., formamide, N,N-dimethylformamide, and N,N-dimethylacetamide), a nitrile (e.g., acetonitrile and propionitrile), a sulfoxide (e.g., dimethylsulfoxide), and a pyrrolidone (e.g., 2-pyrrolidone, 3-pyrrolidone, and N-methyl-2-pyrrolidone). These organic solvents may be used alone or as a mixed solvent.

The amount of the solvent can be selected from the range in which the coating property and the film formability are not damaged. For example, the organic heteropolymer in the composition may have a concentration of about 0.01 to 30% by weight, preferably about 0.05 to 20% by weight (e.g., about 0.1 to 10% by weight).

The composition of the present invention may be prepared by a conventional method, for example, mixing and dissolving the organic heteropolymer in the organic solvent and optionally filtering the resulting mixture.

The organic semiconductor may be produced through a step of applying the composition on a base material or substrate (such as a glass plate, a silicon wafer, or a heat-resisting plastic film) and a step of drying the resulting coat to remove a solvent. The applying method may include a conventional applying method, for example, air knife coating, roll coating, gravure coating, blade coating, dip coating, spraying, spin coating, screen printing, and ink jet printing.

The thickness of the organic semiconductor may suitably be selected according to purposes, and may be, for example, about 1 to 5000 nm, preferably about 30 to 1000 nm, and more preferably about 50 to 500 nm.

The organic semiconductor may be an n-type semiconductor or a p-type semiconductor, or may be an intrinsic semiconductor.

The organic heteropolymer and the organic semiconductor of the present invention have a photoelectric conversion capability, for example, have an improved mobility of electrons and holes generated by absorption of light and an improved photoelectric conversion efficiency. Thus the organic heteropolymer and the organic semiconductor characteristics are utilized for various electronic devices {for example, a photoelectric conversion device or a photoelectric conversion element (such as a solar cell or an organic electroluminescent (EL) device), a rectifier (a diode), and a switching device or a transistor [such as a top-gate transistor or a bottom-gate transistor (a top-contact transistor, a bottom-contact transistor)]}. Representative devices which utilize the organic semiconductor of the present invention may include an organic solar cell, an organic EL, an organic thin-film transistor, or other devices.

The organic solar cell has a pn-junction semiconductor and a surface electrode laminated thereon. For example, a solar cell can be formed by laminating an organic semiconductor film on a p-type silicon semiconductor and laminating a transparent electrode (such as an ITO electrode) on the organic semiconductor film.

The organic EL may include one having a laminated structure of, in sequence, a transparent electrode (such as an ITO electrode), a light-emitting layer containing an organic heteropolymer (a light-emitting polymer) and optionally an electron-transporting material and a hole-transporting material dispersed in the organic heteropolymer, and an electrode (such as a metal electrode).

The organic thin-film transistor comprises a gate electrode layer, a gate insulating layer, a source/drain electrode layer, and an organic semiconductor layer. According to the laminated structure of these layers, the organic thin-film transistor can be classified into a top-gate transistor and a bottom-gate transistor (a top-contact transistor, a bottom-contact transistor). For example, a top-contact field effect transistor can be produced by forming an organic semiconductor film on a gate electrode (e.g., a p-type silicon wafer having an oxide layer formed thereon) and forming a source-drain electrode (a gold electrode) on the organic semiconductor film.

The organic heteropolymer of the present invention is also useful as a sensitizer (or a sensitizing dye) for photoexciting a semiconductor and/or a charge-transporting agent, in addition to the use as the organic semiconductor shown above. The organic heteropolymer is also usable as a sensitizer of the electronic device described above (for example, a photoelectric conversion element such as a solar cell or an organic EL device). The organic heteropolymer can usually be adsorbed (or attached) to a semiconductor (or a surface of a semiconductor) by physical adsorption, chemical adsorption (or chemical bond), or other embodiments to act as a sensitizer or other agents.

The semiconductor may be an organic semiconductor or other semiconductors, or may preferably be an inorganic semiconductor. The inorganic semiconductor may include, for example, a metal as a simple substance (e.g., palladium and platinum) and a metal compound. Examples of the metal compound may include an oxide of any group 4 to 15 metal of the Periodic Table (for example, titanium oxide, niobium oxide, tantalum oxide, chromium oxide, manganese oxide, iron oxide, cobalt oxide, iridium oxide, nickel oxide, copper oxide, zinc oxide, gallium oxide, indium oxide, tin oxide, and bismuth oxide), a sulfide of the metal (for example, CdS and a copper sulfide (CuS, Cu₂S)), a nitride of the metal (for example, thallium nitride), a selenide of the metal (for example, CdSe and ZnSe), a halide of the metal (for example, CuBr), and a complex containing a plurality of the metals (for example, CuAlO₂ and CuGaS₂). These semiconductors may be used alone or in combination.

These semiconductors may be a p-type semiconductor or may preferably be an n-type semiconductor. Representative n-type semiconductors may include, for example, titanium oxide (TiO₂), zinc oxide (ZnO), tin oxide (SnO₂), indium oxide (In₂O₃), gallium oxide (Ga₂O₃), copper-aluminum oxide (CuAlO₂), and a doped form of such a metal oxide. In particular, titanium oxide (TiO₂) is preferred. The titanium oxide may also include TiO₂, Ti₂O₅, Ti₂O₃, a hydrated titanium oxide (such as metatitanic acid or orthotitanic acid). As the titanium oxide, TiO₂ (titanium dioxide) is widely used practically. The titanium oxide may have an amorphous form or a crystal form (such as a rutile form or an anatase form).

The form or configuration of the semiconductor may be a particulate form, a fibrous form, a plate-like form, or other forms, or may preferably be a particulate form. The semiconductor may be a nanoparticle (e.g., a sintered nanoparticle). Specifically, the semiconductor may have an average particle size (e.g., a particle size before sintering) selected from the range of, for example, about 1 to 1000 nm (e.g., about 2 to 700 nm). For example, the semiconductor may have an average particle size of about 3 to 500 nm, preferably about 5 to 300 nm, more preferably about 7 to 100 nm (e.g., about 8 to 70 nm), and particularly about not more than 50 nm (e.g., about 1 to 30 nm).

The ratio of the organic heteropolymer adsorbed or attached to the semiconductor (or semiconductor particle) relative to 1 part by weight of the semiconductor may, for example, be about 0.001 to 1 parts by weight, preferably about 0.005 to 0.5 parts by weight, and more preferably about 0.01 to 0.1 parts by weight.

Further, combining the organic heteropolymer (the sensitizer and/or the charge-transporting agent) of the present invention with the semiconductor allows the photoelectric conversion efficiency to be improved, and is thus useful particularly for forming a dye-sensitized solar cell or others. For example, a layer containing the organic heteropolymer and the semiconductor is laminated as an electrode on a substrate to give a laminate which is utilizable for a dye-sensitized solar cell. The dye-sensitized solar cell comprises, in sequence, this electrode, a sealed electrolyte layer, and a counter electrode. In a case where the semiconductor is an n-type semiconductor, the counter electrode forms a positive electrode (the laminate forms a negative electrode); in a case where the semiconductor is a p-type semiconductor, the counter electrode forms a negative electrode (the laminate is a positive electrode).

The substrate may usually be a conductive substrate. The conductive substrate may comprise an electric conductor (or an electric conductor layer) alone. The conductive substrate may usually include a substrate having an electric conductor layer (or a conductive layer or a conductive film) formed on a base plate, or other substrates.

The base plate may include an inorganic plate (e.g., a glass), an organic plate (e.g., a plastic plate), or other plates. As the base plate, a transparent plate (a transparent inorganic plate) is practically used.

The electric conductor may include, for example, an electric conductor such as a conductive metal oxide [for example, tin oxide, indium oxide, zinc oxide, a tin-doped metal oxide (e.g., a tin-doped indium oxide), and a fluorine-doped metal oxide (e.g., a fluorine-doped tin oxide)]. These electric conductors may be used alone or in combination. A preferred electric conductor includes a transparent electric conductor.

The laminate may be formed (i) by applying (or coating) a composition (e.g., a paste) containing the organic heteropolymer, which can form a film, and the semiconductor on a substrate and drying the composition or (ii) by applying the semiconductor on a substrate, heat-treating (or sintering) the coated product at a high temperature (about 400 to 500° C.), and then adsorbing the organic heteropolymer to the semiconductor layer.

In the method (i), the composition (e.g., a paste) usually contains a solvent. As the solvent, there may be used the above-exemplified organic solvent.

In the method (ii), the organic heteropolymer may be adsorbed or attached to the semiconductor layer by immersing the substrate having the semiconductor layer laminated thereon in a solution containing the organic heteropolymer, or other means. A solvent in the solution may be the above-exemplified organic solvent.

In the methods (i) and (ii), the applying (or coating) method may include the above-exemplified applying method (for example, spin coating and screen printing).

The semiconductor layer (the photoelectric conversion layer) containing the organic heteropolymer laminated on the substrate may have a thickness of, for example, about 0.1 to 100 μm, preferably about 0.5 to 50 μm, and more preferably about 1 to 30 μm (e.g., about 5 to 20 μm).

The counter electrode comprises the conductive substrate shown above and a catalyst layer (for example, a conductive metal (such as gold or platinum), carbon, or others) formed on the conductive substrate.

The electrolyte layer may be formed of an electrolytic solution containing an electrolyte and a solvent or may be formed of a solid layer (or a gel) containing an electrolyte. The electrolyte may include a widely used electrolyte, for example, a combination of a halogen and a halide salt (e.g., a combination of iodine and an iodide salt). The counter ion constituting the halide salt may include a metal ion (such as an alkali metal ion or an alkaline earth metal ion), a quaternary ammonium ion (such as an imidazolium salt), or other ions. The electrolytes may be used alone or in combination. As the solvent, there may be used a widely used solvent, for example, an organic solvent such as the above-exemplified alcohol, nitrile, ether, sulfoxide, or amide, and water. The solvents may be used alone or in combination.

Thus, the photoelectric conversion element that contains the organic heteropolymer of the present invention as a sensitizer and/or a charge-transporting agent achieves high short-circuit current and open-circuit voltage.

### EXAMPLES

The following examples are intended to describe this invention in further detail and should by no means be interpreted as defining the scope of the invention. For use in working examples, each of cyclopentyl methyl ether, tetrahydrofuran (THF), and diethyl ether was dried over sodium and then distilled in a nitrogen atmosphere or under an air flow. Tetraisopropoxytitanium (Ti(OPrⁱ)₄) was purified by distillation under reduced pressure.

The characteristics of the resulting polymers ware measured by the following methods.

[¹H-NMR Spectrum and ³¹P-NMR Spectrum]

The ¹H-NMR spectrum and ³¹P-NMR spectrum were measured by a 300-MHz NMR apparatus (“JNM-ECP300” manufactured by JEOL Ltd.) using tetramethylsilane (TMS) as an internal standard and CDCl₃ as a solvent.

[Molecular Weight]

The molecular weight and molecular weight distribution of a polymer was measured by gel permeation chromatography (GPC) (solvent: tetrahydrofuran (THF), in terms of polystyrene).

[Ultraviolet-Visible Light Absorption Spectrum and Emission Spectrum]

A polymer was dissolved in chloroform to give a polymer solution having a concentration or 20 mg/5 ml, and the ultraviolet-visible light absorption spectrum of the polymer solution was measured by “UV-3100PC” manufactured by Shimadzu Corporation. The emission spectrum of the same polymer solution was measured by “RF-5300PC” manufactured by Shimadzu Corporation. The maximum absorption wavelength of the polymer was set as an excitation light wavelength.

### Example 1

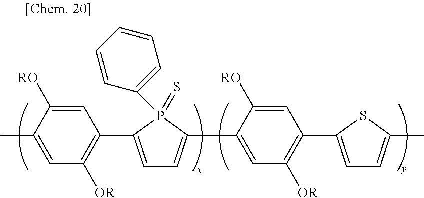

In the formula, R represents 2-ethylhexyl group; each of x and y represents a ratio (a molar ratio) of the corresponding constitutional unit; and x:y=0.44:0.56.

Under an argon atmosphere, 1,4-diethynyl-2,5-bis(2-ethylhexyloxy)benzene (0.191 g, 0.500 mmol) and tetraisopropoxytitanium (Ti(OPrⁱ)₄) (0.198 g, 0.700 mmol) were dissolved in cyclopentyl methyl ether (20 ml). To the resulting solution, a solution of isopropylmagnesium chloride (ⁱPrMgCl) in diethyl ether (1.0 N, 1.25 ml, 1.25 mmol) was further added while stirring at −78° C. Thereafter, the mixture was gradually heated to −50° C. and stirred for 12 hours, and dichlorophenylphosphine (0.053 g, 0.300 mmol) and disulfur dichloride (0.041 g, 0.300 mmol) were gradually added to the mixture at this temperature. The resulting mixture was slowly heated to a room temperature and was stirred for another 12 hours. Water was added to the resulting reaction solution, and the mixture was subjected to chloroform extraction and then reprecipitation by hexane to give a red polymer represented by the above formula at a yield of 76% (0.176 g, 0.38 mmol). The resulting polymer had a number-average molecular weight Mn of 11000 and a molecular weight distribution Mw/Mn of 3.4. The ¹H-NMR and ³¹P-NMR spectra of the polymer are shown below. From the results of the ¹H-NMR spectrum, the ratio of the constitutional unit having a sulfureted phosphole skeleton relative to the constitutional unit having a thiophene skeleton, x:y, was determined to be 0.44:0.56.

¹H-NMR (300 MHz, CDCl₃, ppm): 0.88-0.95 (12H, —CH₃): 1.31-1.76 (18H, —OCH₂CH(CH₂CH₃)CH₂CH₂CH₂CH₃): 3.21-4.08 (br, 4H, —O—CH₂—): 6.24-8.31 (aromatic, 4H+5H×x)

³¹P-NMR (122 MHz, CDCl₃, ppm): 54.0

### Comparative Example 1

A polymer represented by the following formula was obtained in the same manner as Example 6 described in Japanese Patent Application Laid-Open Publication No. 2013-155229.

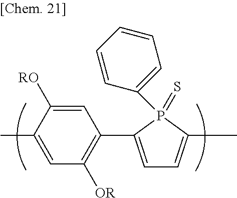

In the formula, R represents 2-ethylhexyl group.

### Comparative Example 2

A polymer represented by the following formula was obtained in the same manner as Example 1 described in Japanese Patent Application Laid-Open Publication No. 2013-185009 except that disulfur dichloride (S₂Cl₂) was used instead of tellurium tetrachloride in Example 1 of this publication.

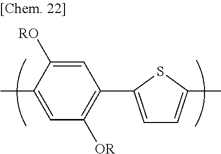

In the formula, R represents 2-ethylhexyl group.

### Comparative Example 3

A mixture containing the polymer of Comparative Example 1 and the polymer of Comparative Example 2 in a molar ratio (the former:the latter) of 1:1 was prepared and was used as Comparative Example 3.

(Measurements of Ultraviolet-Visible Light Absorption Spectrum and Emission Spectrum)

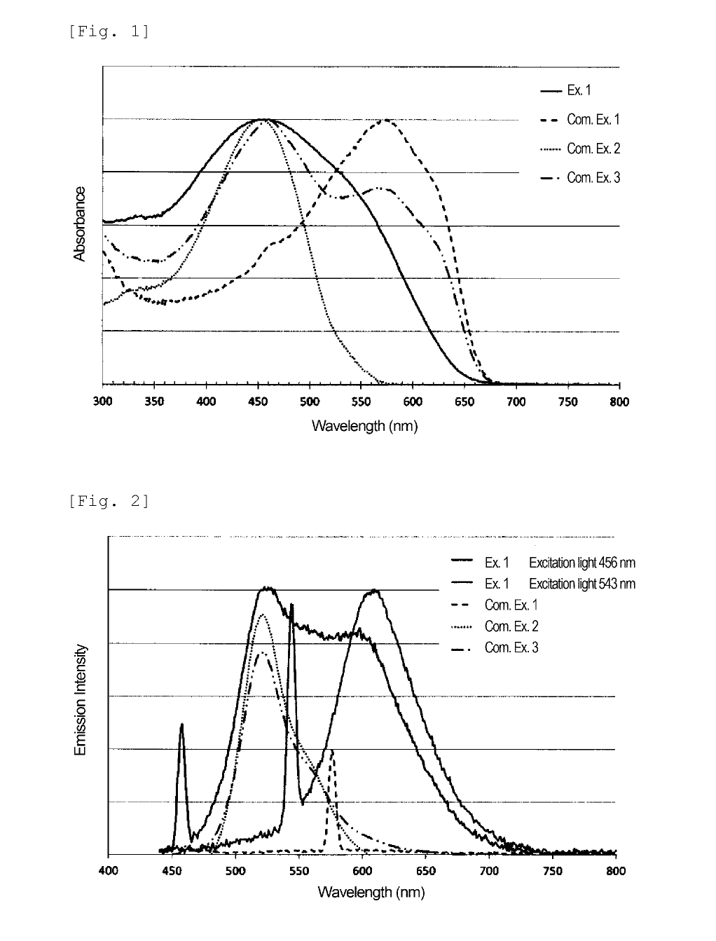

FIG. 1 shows the measurements of the ultraviolet-visible light absorption spectra of the polymers obtained in Example 1, Comparative Example 1, Comparative Example 2, and Comparative Example 3.

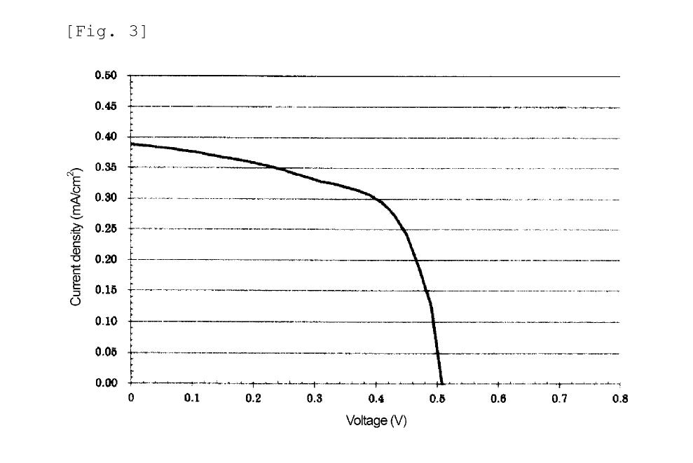

FIG. 2 shows the measurements of the emission spectra of the polymers. For the polymer of Example 1, the spectrum at an excitation light wavelength of 543 nm (shoulder peak) and that at an excitation light wavelength of 456 nm (maximum absorption wavelength) were shown.

As apparent from FIG. 1, the polymer of Example 1 shows a high absorbance in a wider wavelength range compared with the polymers of Comparative Example 1 and 2 and the polymer mixture of Comparative Example 3. As apparent from FIG. 2, the polymer of the present invention has a wider light-emitting range and more excellent light emission characteristics compared with the polymers of Comparative Example 1 and 2 and the polymer mixture of Comparative Example 3.

### Example 2

An FTO glass (model number FTB manufactured by Astellatech, Inc.) was washed with acetone, and a titanium oxide paste (“Ti-Nanoxide T/SP” manufactured by SOLARONIX) was applied on the FTO glass by screen printing to form a 4-mm square coat having a thickness of 10 μm. The resulting product was dried at 100° C. by a hot plate and was then baked at 500° C. for one hour to give a titanium oxide electrode.

The polymer obtained in Example 1 was dissolved in THF to give a 0.1% by weight solution. The above titanium oxide electrode was immersed in the solution, and was allowed to stand under a room temperature for 24 hours for adsorbing the polymer obtained in Example 1 to the surface of the titanium oxide. After adsorption, the titanium oxide electrode was removed from the solution, was washed with THF, and was dried to give a polymer-adsorbed titanium oxide electrode. A platinum thin film (thickness 0.003 μm) was formed on an ITO-attached glass substrate (manufactured by GEOMATEC Co., Ltd., 10 Ω/sq) by sputtering to give a counter electrode of the polymer-adsorbed titanium oxide electrode. A spacer (“Himilan” manufactured by DUPONT-MITSUI POLYCHEMICALS CO., LTD.) was interposed between the ITO layer (the platinum thin film side) and the FTO layer of the polymer-adsorbed titanium oxide electrode (the polymer-adsorbed side), and an electrolytic solution was filled with a space between both substrates (or a space sealed by a sealant) to give a dye-sensitized solar cell. As the electrolytic solution, an acetonitrile solution containing 0.5 mol/L 1,2-dimethyl-3-propylimidazolium iodide, 0.1 mol/L lithium iodide, and 0.05 mol/L iodine was used.

The resulting dye-sensitized solar cell was evaluated under the conditions of a spectral distribution AM 1.5, 100 mW/cm², and 25° C. by a solar simulator (“XES-301S+EL-100” manufactured by SAN-EI ELECTRIC CO., LTD.). The resulting electric current density-potential characteristics are shown in FIG. 3.

As shown in FIG. 3, use of the polymer obtained in Example 1 as a sensitizing dye enables formation of a dye-sensitized solar cell.

### INDUSTRIAL APPLICABILITY

The organic heteropolymer of the present invention is a π-conjugated polymer and is useful for forming an organic semiconductor (a polymeric organic semiconductor) having a low resistance and a high conductivity. The organic semiconductor is utilizable for various devices, for example, a rectifier (a diode), a switching device or a transistor [such as a junction transistor (a bipolar transistor) or a field-effect transistor (a unipolar transistor)], and a photoelectric conversion element (such as a solar cell or an organic EL device). The organic heteropolymer of the present invention also has an activity of photoexciting a semiconductor and is thus utilizable as a sensitizer (or a sensitizing dye) of the electronic device (e.g., a photoelectric conversion element such as a solar cell or an organic EL device).

1. An organic heteropolymer having a constitutional unit represented by the following formula (1) and a constitutional unit represented by the following formula (2): 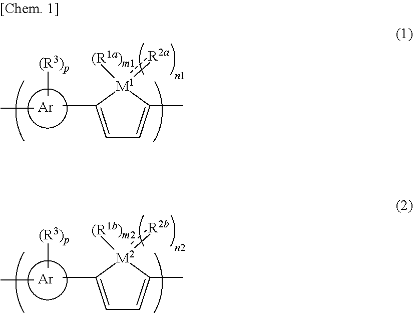
wherein M¹ and M² each represent a heteroatom selected from the group consisting of a group 8 element, a group 9 element, a group 10 element, a group 14 element, a group 15 element, and a group 16 element of the Periodic Table, and M¹ and M² are different in group from each other,
M¹ and M² each have a valence v of 2 to 6,
R^{1a} and R^{1b} are the same or different and each represent a halogen atom, an alkyl group, a cycloalkyl group, an aryl group, or a heteroaryl group,
R^{2a} and R^{2b} are the same or different and each represent a halogen atom, an alkyl group, a cycloalkyl group, an aryl group, a heteroaryl group, a univalent or bivalent heteroatom selected from the group consisting of a group 16 element and a group 11 element of the Periodic Table, or a metal atom forming a complex with a ligand, [symbol]
[Chem. 2]
represents a single bond or a double bond,
m1, m2, n1, and n2 each denote 0 or 1,
a ring Ar represents an aromatic ring,
R³ represents a straight- or branched-chain alkyl group, a straight- or branched-chain alkoxy group, or a straight- or branched-chain alkylthio group, and
p denotes 0 or an integer of 1 to 3.

2. The organic heteropolymer according to claim 1, which comprises a random copolymer having the constitutional unit represented by the formula (1) and the constitutional unit represented by the formula (2), wherein a ratio (molar ratio) of the constitutional unit represented by the formula (1) relative to the constitutional unit represented by the formula (2) is 99/1 to 1/99 in the former/the latter.

3. The organic heteropolymer according to claim 1, which has a constitutional unit represented by the following formula (3) and a constitutional unit represented by the following formula (4): 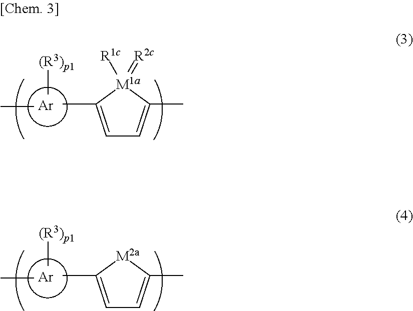
wherein M^{1a} represents a group 15 element of the Periodic Table,
M^{2a} and R^{2c} each represent a group 16 element of the Periodic Table,
R^{1c} represents an alkyl group, an aryl group, or a heteroaryl group,
p1 denotes an integer of 1 to 3, and
the ring Ar and R³ have the same meanings as defined in claim 1.

4. The organic heteropolymer according to claim 1, wherein the ring Ar is represented by the following formula (5): 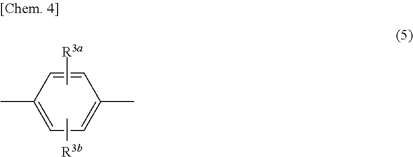
wherein R^{3a} and R^{3b} are the same or different and each represent a straight- or branched-chain C₄₋₁₂alkyl group, a straight- or branched-chain C₄₋₁₂alkoxy group, or a straight- or branched-chain C₄₋₁₂alkylthio group.

5. A process for producing an organic heteropolymer recited in claim 1, which comprises allowing a polymer having a constitutional unit represented by the following formula (8): 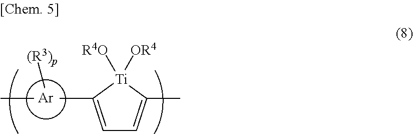
wherein R⁴ represents an alkyl group, and
R³, the ring Ar, and p have the same meanings as defined in claim 1,
to react with a halide represented by the following formula (9) and a halide represented by the following formula (10): 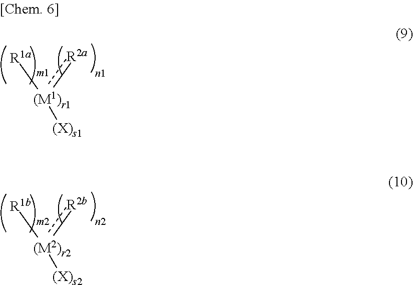
wherein X represents a halogen atom,
M¹ has a valence v¹ of 2 to 6,
M² has a valence v² of 2 to 6,
r1 and r2 each denote an integer of 1 to 3,
s1 and s2 each denote an integer of 1 to 6,
the valences v¹ and v² each satisfy the following equations: v¹=m1+n1+s1, v²=m2+n2+s2, [symbol]
[Chem. 7]
represents a single bond or a double bond,
provided that, when [symbol] represents a double bond, the valences v¹ and v² each satisfy the following equations: v¹=m1+2×n1+s1, v²=m2+2×n2+s2, and
M¹, M², R^{1a}, R^{1b}, R^{2a}, R^{2b}, m1, m2, n1, and n2 have the same meanings as defined in claim 1.

6. A process for producing an organic heteropolymer recited in claim 1, which comprises allowing a polymer having a constitutional unit represented by the formula (8): 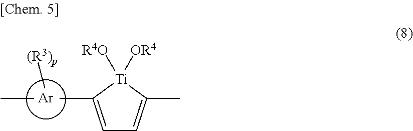
wherein R⁴ represents an alkyl group, and
R³, the ring Ar, and p have the same meanings as defined in claim 1,
to react with a halide represented by the following formula (9A) and a halide represented by the following formula (10A): 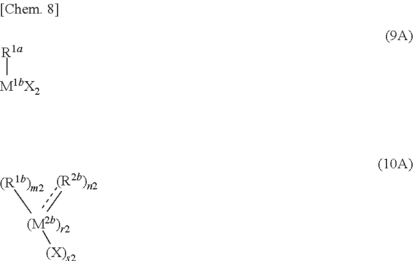
wherein M^{1b} represents a heteroatom selected from a group 15 element of the Periodic Table,
M^{2b} represents a heteroatom selected from the group consisting of a group 8 element, a group 9 element, a group 10 element, a group 14 element, and a group 16 element of the Periodic Table,
M^{2b} has a valence v^{2b} of 2 to 6,
the valence v^{2b} satisfies the following equation: v^{2b}=m2+n2+s2, [symbol]
[Chem. 9]
represents a single bond or a double bond,
provided that, when [symbol] represents a double bond, the valence v^{2b} satisfies the following equation: v^{2b}=m2+2×n2+s2, and
r2 each denote an integer of 1 to 3,
s2 each denote an integer of 1 to 6,
R^{1a}, R^{1b}, R^{2b}, r2, s2, m2, n2, and X have the same meanings as defined in claim 1, to give an organic heteropolymer having a constitutional unit represented by the following formula (1A) and a constitutional unit represented by the following formula (2A): 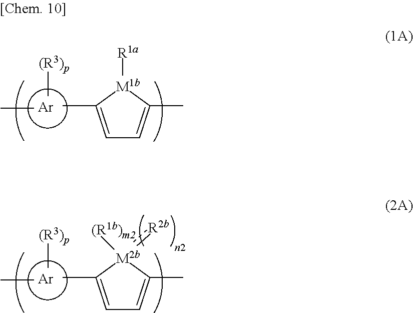
wherein [symbol]
[Chem. 11]
represents a single bond or a double bond,
M^{1b} and M^{2b} have the same meanings as defined above,
R^{1a}, R^{1b}, R^{2b}, R³, the ring Ar, m2, n2, and p have the same meanings as defined in claim 1; and
allowing the organic heteropolymer to react with a compound represented by the following formula (11) or an elemental substance represented by the following formula (12):
[Chem. 12]
L-R^{2a1} (11)
R^{2a2} (12)
wherein R^{2a1} represents a metal atom forming a complex with a ligand,
L represents a leaving group, and
R^{2a2} represents an elemental substance selected from a group 16 element of the Periodic Table.

7. (canceled)

8. An organic semiconductor comprising an organic heteropolymer recited in claim 1.

9. An electronic device comprising an organic heteropolymer recited in claim 1.

10. (canceled)

11. The electronic device according to claim 9, which is a photoelectric conversion element, a switching device, or a rectifier.
